(19) United States
(12) Patent Application Publication
(10) Pub. No.: US 2009/0141083 A1
(43) Pub. Date: Jun. 4, 2009

(54) INKJET PRINTHEAD AND METHOD OF MANUFACTURING THE SAME

(75) Inventors: Dong-sik SHIM, Suwon-si (KR); Yong-seop Yoon, Seoul (KR); Moon-chul Lee, Seongnam-si (KR); Yong-won Jeong, Seoul (KR); Hyung Choi, Seongnam-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/114,982

(22) Filed: May 5, 2008

(30) Foreign Application Priority Data
Dec. 4, 2007 (KR) 2007-124907

(51) Int. Cl. B41J 2/16; H01L 21/00

(52) U.S. Cl. 347/47; 438/21; 257/E21.001

(57) ABSTRACT

An inkjet printhead and a method of manufacturing the same. The inkjet printhead includes a silicon on insulator (SOI) substrate including a lower silicon substrate, a middle insulating layer, an upper silicon substrate, and an ink feed hole, the ink feed hole penetrates the SOI substrate to supply ink, an insulating layer stacked on the upper silicon substrate of the SOI substrate, a chamber layer stacked on the insulating layer in which a plurality of ink chambers filled with ink supplied from the ink feed hole is formed, a nozzle layer stacked on the chamber layer in which a plurality of nozzles is formed to correspond to the ink chambers, a plurality of heaters formed on the insulating layer which heats ink in the ink chambers to generate bubbles and eject ink through the nozzles, and a driving circuit region on which a driving circuit is formed to drive the heaters.

### CROSS-REFERENCE TO RELATED APPLICATIONS

This application claims priority under 35 U.S.C. §119(a) Korean Patent Application No. 10-2007-0124907, filed on Dec. 4, 2007, in the Korean Intellectual Property Office, the disclosure of which is incorporated herein in its entirety by reference.

### BACKGROUND OF THE INVENTION

1. Field of the Invention

The present general inventive concept relates to an inkjet printhead, and more particularly, to a thermal inkjet printhead with a reliable configuration and a method of manufacturing the same.

2. Description of the Related Art

In general, an inkjet printhead is a device which forms an image with a predetermined color by ejecting a small amount of ink droplet of onto a desired position of a printed medium. Such inkjet printhead can be classified into two types according to an ejecting mechanism of ink. One is a thermal inkjet printhead which generates bubbles in ink by using a heat source and ejects ink droplet by an expansive force of such bubbles. The other is a piezoelectric inkjet printhead which uses a piezoelectric substance and ejects ink droplet by pressure applied to ink due to transformation of the piezoelectric substance.

An ejecting mechanism of ink droplet in the thermal inkjet printhead is now described in more detail.

When a pulse type current flows through a heater formed of resistance heating materials, heat is generated from the heater, and thus, ink adjacent to the heater is heated in an instant. Accordingly, ink is boiled and bubbles are generated. The generated bubbles expand, thereby applying a pressure to ink filled in an ink chamber. Thus, ink adjacent to a nozzle is ejected out to the ink chamber through the nozzle in a form of a droplet.

FIG. 1 is a sectional diagram schematically illustrating a conventional thermal inkjet printhead. Referring to FIG. 1, the conventional inkjet printhead includes a substrate 10 on which a plurality of material layers are formed, a chamber layer 20, and a nozzle layer 30, wherein the chamber layer 20 is stacked on the substrate 10, and the nozzle layer 30 is stacked on the chamber layer 20. The chamber layer 20 includes a plurality of ink chambers 22 with which ink to be ejected is filled and the nozzle layer 30 includes a plurality of nozzles 32 through which ink is ejected. Also, an ink feed hole 11 for supplying ink to the ink chambers 22 is formed in the substrate 10. Moreover, the chamber layer 20 may include a plurality of restrictors 24 which connects the ink chambers 22 with the ink feed hole 11.

Meanwhile, an insulating layer 12 is formed on the substrate 10 for insulating between a plurality of heaters 14 and the substrate 10. Also, a plurality of heaters 14 is formed on the insulating layer 12 for heating ink and thus generating bubbles. An electrode 16 for applying electricity to the heater 14 is formed on the heater 14. In addition, a driving circuit region 13 in which a driving circuit for driving the heater 14 is formed is formed in the upper part of the substrate 10 and the heater 14 is electrically connected to the driving circuit region 13 through a penetrating region (not illustrated) formed in the insulating layer 12.

A passivation layer 18 is formed on the surfaces of the heater 14 and the electrode 16 for protecting the heater 14 and the electrode 16. On the passivation layer 18, an anti-cavitation layer 19 for protecting the heater 14 from being damaged by cavitation force generated when the bubbles collapse is formed.

In manufacturing the inkjet printhead with above configuration, the ink feed hole 11 can be formed after forming an etching mask on a bottom surface of the substrate 10 and wet etching or dry etching for the ink feed hole 11 to penetrate the exposed substrate 10 through the etching mask. However, while forming the ink feed hole 11 which penetrates the substrate 10 through such etching process, misalignment of the ink feed hole 11 may be generated and in this case, the driving circuit region 13 may be damaged. In addition, while forming the ink feed hole 11 by etching a portion having a lowest etching speed, another portion of the ink feed hole 11 can be over-etched and the driving circuit region 13 may be damaged by such over-etching. As described above, when the ink feed hole 11 penetrating the substrate 10 is formed by using the etching process in the conventional inkjet printhead, reliability of the inkjet printhead may decrease.

### SUMMARY OF THE INVENTION

The present general inventive concept provides an inkjet printhead with a reliable configuration and a method of manufacturing the same.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept are achieved by providing an inkjet printhead including a silicon on insulator (SOI) substrate comprising a lower silicon substrate, a middle insulating layer, an upper silicon substrate, and an ink feed hole, the ink feed hole to penetrate the SOI substrate to supply ink, an insulating layer stacked on the upper silicon substrate of the SOI substrate, a chamber layer stacked on the insulating layer in which a plurality of ink chambers filled with ink supplied from the ink feed hole is formed, a nozzle layer stacked on the chamber layer in which a plurality of nozzles is formed to correspond to the ink chambers; a plurality of heaters formed on the insulating layer which heats ink in the ink chambers to generate bubbles and eject ink through the nozzles, and a driving circuit region on which a driving circuit is formed to drive the heaters.

The driving circuit region may be formed in the upper silicon substrate of the SOI substrate. The ink feed hole may include a lower feed hole formed in the lower silicon substrate, a middle feed hole formed in the middle insulating layer, and an upper feed hole formed in the upper silicon substrate.

The foregoing and/or other aspects and utilities of the present general inventive concept are also achieved by providing a method of manufacturing an inkjet printhead, the method including, preparing a silicon on insulator (SOI) substrate in which a lower silicon substrate, a middle insulating layer, and an upper silicon substrate are sequentially stacked, forming a driving circuit region in the upper silicon substrate of the SOI substrate and then forming an insulating layer on the upper silicon substrate, forming heaters and electrodes on the insulating layer, forming a trench in the insulating layer to expose the upper silicon substrate and then forming an upper feed hole to connect to the trench in the upper silicon substrate, stacking a chamber layer, in which a plurality of ink chambers is formed, on the insulating layer, stacking a nozzle layer, in which a plurality of nozzles is formed, on the chamber layer, and forming a lower feed hole on the lower silicon substrate of the SOI substrate and forming a middle feed hole to connect the lower feed hole and the upper feed hole in the middle insulating layer.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a sectional diagram schematically illustrating a conventional thermal inkjet printhead;

FIG. 2 is a plan view illustrating an inkjet printhead according to an embodiment of the present general inventive concept;

FIG. 3 is a sectional diagram of the inkjet printhead of FIG. 2 viewed from a line III-III′ of FIG. 2; and

FIGS. 4-9 are diagrams illustrating a method of manufacturing an inkjet printhead according to an embodiment of the present general inventive concept.

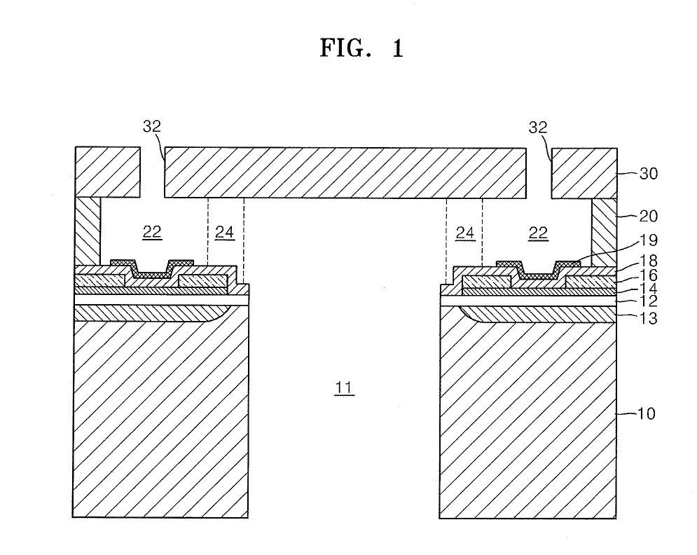

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

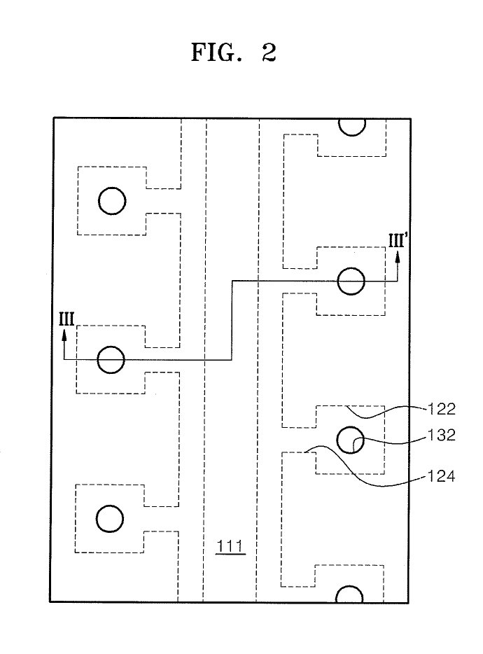

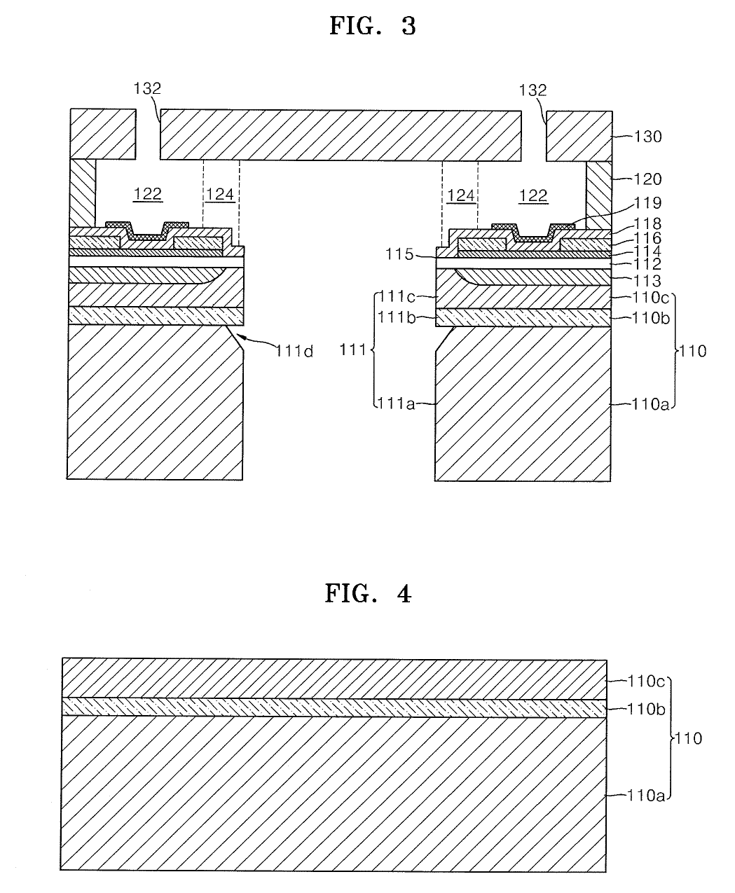

FIG. 2 is a plan view illustrating an inkjet printhead according to an embodiment of the present general inventive concept and FIG. 3 is a sectional diagram of the inkjet printhead of FIG. 2 viewed from the line III-III′ of FIG. 2.

Referring to FIGS. 2 and 3, the inkjet printhead includes a substrate 110, a chamber layer 120, and a nozzle layer 130, wherein the chamber layer 120 is stacked on the substrate 110 and the nozzle layer 130 is stacked on the chamber layer 120. Here, the chamber layer 120 includes a plurality of ink chambers 122 and the nozzle layer 130 includes a plurality of nozzles 132.

The substrate 110 may be a silicon substrate. More specifically, the substrate 110 may be formed of a silicon on insulator (SOI) substrate on which a lower silicon substrate 110a, a middle insulating layer 110b, and an upper silicon substrate 110c are sequentially stacked. Here, the middle insulating layer 110b may be formed of a silicon oxide. The middle insulating layer 110b may have a thickness of 0.1 μm or greater, for example, 0.1-0.5 μm. The upper silicon substrate 110c may have a thickness of 1 μm or greater, for example, 1-5 μm. An ink feed hole 111 is formed by penetrating the substrate 110 to supply ink to the ink chambers 122. The ink feed hole 111 is formed of a lower feed hole 111a, middle feed hole 111b, and an upper feed hole 111c. The lower feed hole 111a, the middle feed hole 111b, and the upper feed hole 111c penetrate the lower silicon substrate 110a, the middle insulating layer 110b, and the upper silicon substrate 110c, respectively.

An insulating layer 112 may be formed on an upper surface of the substrate 110 to insulate between the substrate 110 and the heater 114. Here, the insulating layer 112 may be formed of, for example, a silicon oxide. Also, a plurality of the heaters 114 may be formed on an upper surface of the insulating layer 112. The heaters 114 serve to heat an ink in the ink chambers 122 and thus to generate bubbles. Here, the heaters 114 may be disposed at lower portions of the ink chambers 122. The heaters 114 may be formed of, for example, heating material resistors, such as tantalum-aluminum alloy, tantalum nitride, titanium nitride, or tungsten silicide. Moreover, electrodes 116 may be formed on upper surfaces of the heaters 114. The electrodes 116 apply a current to the heater 114 and may be formed of materials having excellent electric conductivity. For example, the electrodes 116 may be formed of aluminum (Al), an aluminum alloy, gold (Au), and silver (Ag).

A driving circuit region 113 in which a driving circuit to drive the heaters 114 may be formed is formed on an upper part of the upper silicon substrate 110c of the SOI substrate 110 and the electrodes 116 connected to the heaters 114 are electrically connected to the driving circuit of the driving circuit region 113 through a penetrating region (not illustrated) formed in the insulating layer 112. Here, the driving circuit of the driving circuit region 113 may be a Complementary Metal-Oxide-Semiconductor (CMOS) circuit.

A passivation layer 118 may be further formed on upper surfaces of the heaters 114 and the electrodes 116. The passivation layer 118 prevents the heaters 114 and the electrodes 116 from being oxidized or corroded by contacting ink and may be formed of, for example, silicon nitride or silicon oxide. Also, an anti-cavitation layer 119 may be further formed on the passivation layer 118, specifically, on an upper surface of the passivation layer 118 disposed on the upper part of a heating portion of the heater 114. Here, the anti-cavitation layer 119 protects the heaters 114 from being damaged by a cavitation force generated when the bubbles collapse and may be formed of, for example, tantalum (Ta). Moreover, a trench 115 is formed in the passivation layer 118 and the insulating layer 112 so as to connect with the ink feed hole 111. The chamber layer 120 is stacked on the SOI substrate 110. The chamber layer 120 includes a plurality of the ink chambers 122 with which ink supplied from the ink feed hole 111 is filled. Here, the ink chambers 122 can be disposed on both sides of the ink feed hole 111. Meanwhile, a plurality of restrictors 124 which is a path connecting the ink feed hole 111 with the ink chambers 122 may be further formed in the chamber layer 120. The nozzle layer 130 is stacked on the chamber layer 120. The nozzles 132 through which ink in the ink chambers 122 is ejected to the outside are formed in the nozzle layer 130.

As described above, in the inkjet printhead according to an embodiment of the present general inventive concept, the driving circuit region 113 is formed in the upper silicon substrate 110c of the SOI substrate 110 and the driving circuit region 113 is separated from the lower feed hole 111a by the middle insulating layer 110b. Accordingly, while forming the lower feed hole 111a, the driving circuit region 113 can be protected from an undercut region 111d which may be formed during an etching process. Also, while forming the lower feed hole 111a, although misalignment of the lower feed hole 111a may be generated, the driving circuit region 113 can be prevented from being damaged by the lower feed hole 111a.

Hereinafter, a method of manufacturing the inkjet printhead according to an embodiment of the present general inventive concept will be described. FIGS. 4-9 are diagrams illustrating a method of manufacturing the inkjet printhead.

FIG. 4 illustrates preparing the SOI substrate 110 for manufacturing the inkjet printhead. The SOI substrate 110 includes the lower silicon substrate 110a, the middle insulating layer 110b, and the upper silicon substrate 110c sequentially stacked thereon. Here, the middle insulating layer 110b may be formed of a silicon oxide. The middle insulating layer 110b may have a thickness of 0.1 μm or greater, for example, 0.1-0.5 μm. The upper silicon substrate 110c may have a thickness of 1 μm or greater, for example, 1-5 μm.

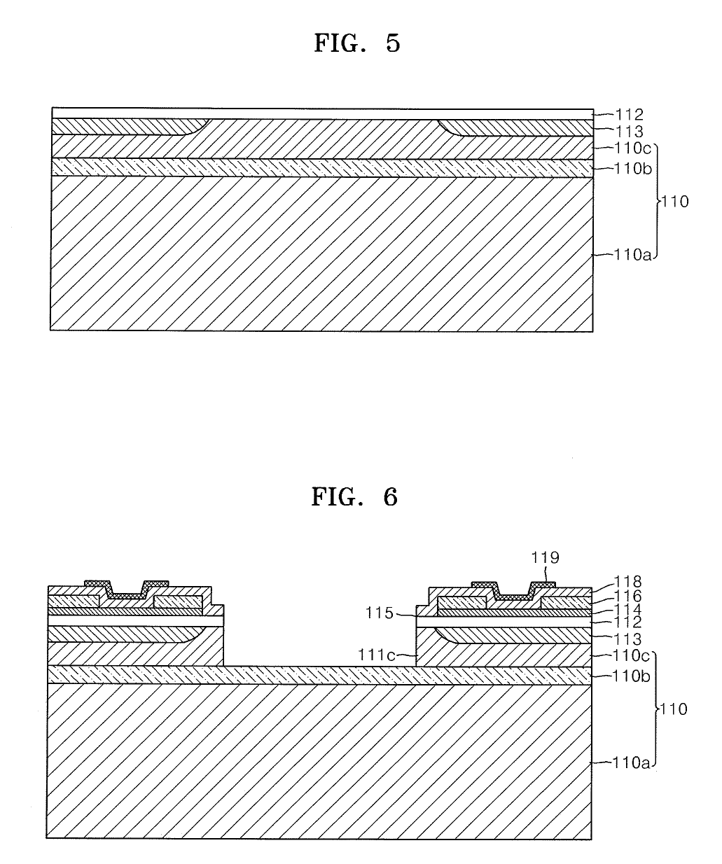

In FIG. 5, the driving circuit region 113 to drive the heater to be formed later is formed in the upper part of the upper silicon substrate 110c of the SOI substrate 110 and the insulating layer 112 is formed on the upper surface of the upper silicon substrate 110c. Here, the driving circuit region 113 may be formed by using a Complementary Metal-Oxide-Semiconductor (CMOS) process. In addition, the insulating layer 112 insulates between the heater 114 formed on the insulating layer 112 and the substrate 110.

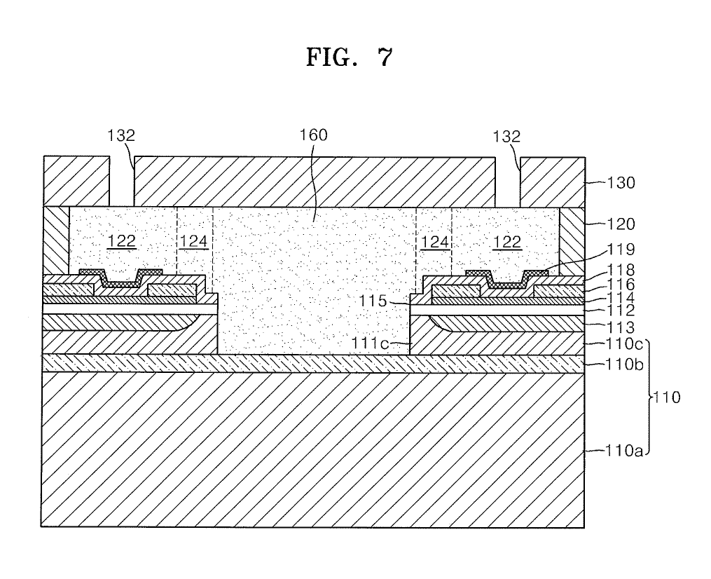

In FIG. 6, the heater 114, the electrode 116, the passivation layer 118, and the anti-cavitation layer 119 are sequentially formed on the insulating layer 112. Also, the trench 115 which exposes the upper silicon substrate 110c of the SOI substrate and the upper feed hole 111c which exposes the middle insulating layer 110b of the SOI substrate are formed. More specifically, the heater 114 can be formed by depositing heating material resistors, such as tantalum-aluminum alloy, tantalum nitride, titanium nitride, or tungsten silicide, on the upper surface of the insulating layer 112 and then patterning the deposited material. Then, the electrode 116 is formed on the upper surface of the heater 114 to apply a current to the heater 114. The electrode 116 can be formed by depositing metal having excellent electric conductivity, for example, aluminum, an aluminum alloy, gold, or silver, on the upper surface of the heaters 114 and then patterning the deposited metal. The passivation layer 118 may be further formed on the insulating layer 112 to cover the heaters 114 and the electrode 116. The passivation layer 118 prevents the heaters 114 and the electrode 116 from being oxidized or corroded by contacting ink and may be formed of, for example, silicon nitride or silicon oxide. Also, the anti-cavitation layers 119 may be further formed on the upper surface of the passivation layer 118. The anti-cavitation layers 119 protect the heaters 114 from being damaged by cavitation force generated when bubbles collapse and may be formed of, for example, tantalum (Ta).

Next, the passivation layer 118 and the insulating layer 112 are sequentially etched to form the trench 115 which exposes the upper silicon substrate 110c of the SOI substrate 110 and then, the upper silicon substrate 110c is etched to form the upper feed hole 111c. Accordingly, the heaters 114 and the electrodes 116 are disposed at both sides of the trench 115 and the driving circuit region 113 is disposed at both sides of the upper feed hole 111c.

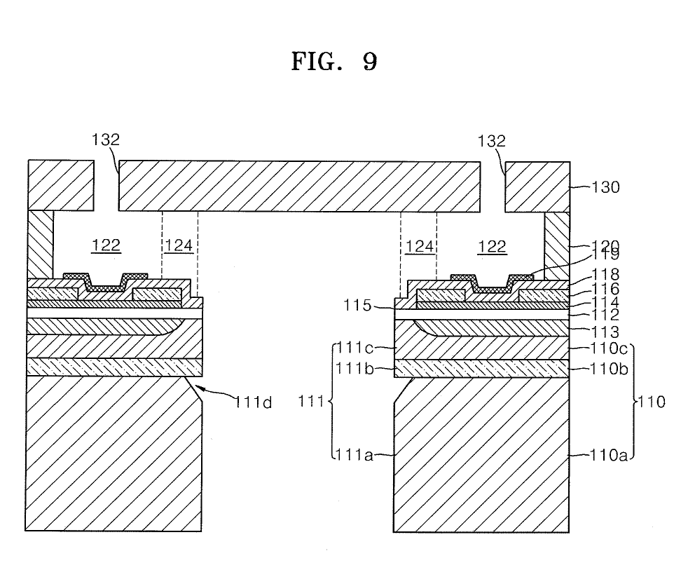

In FIG. 7, the chamber layer 120 in which a plurality of the ink chambers 122 are formed is formed on the passivation layer 118 and a sacrificial layer 160 is formed. Then, the nozzle layer 130 in which a plurality of the nozzles 132 is formed is formed. Firstly, the chamber layer 120 in which the ink chambers 122 are formed is formed on the passivation layer 118. More specifically, a chamber material layer (not illustrated) is applied by a predetermined thickness to cover a structure illustrated in FIG. 6 and then is patterned so as to form the chamber layer 120. Here, the ink chambers 122 may be positioned on upper portions of the heaters 114. Also, the restrictors 124, which are paths to connect the ink chambers 122 to the ink feed hole (111 of FIG. 9) to be formed later, may be further formed in the chamber layer 120.

After the chamber layer 120 is formed, the sacrificial layer 160 is formed to fill the upper feed hole 111c, the trench 115, the ink chambers 122, and the restrictors 124. Then, the upper surface of the sacrificial layer 160 can be flattened through, for example, a chemical mechanical polishing (CMP) process. After the sacrificial layer 160 is formed, the nozzle layer 130 in which a plurality of the nozzles 132 are formed is formed on the upper surfaces of the chamber layer 120 and the sacrificial layer 160. The nozzle layer 130 can be formed after forming a nozzle material layer (not illustrated) on the upper surface of the chamber layer 120 and the sacrificial layer 160 and then patterning the nozzle material layer. Accordingly, a plurality of the nozzles 132 which exposes the upper surface of the sacrificial layer 160 is formed in the nozzle layer 130. Here, the nozzles 132 may be positioned on the upper portions of the ink chambers 122.

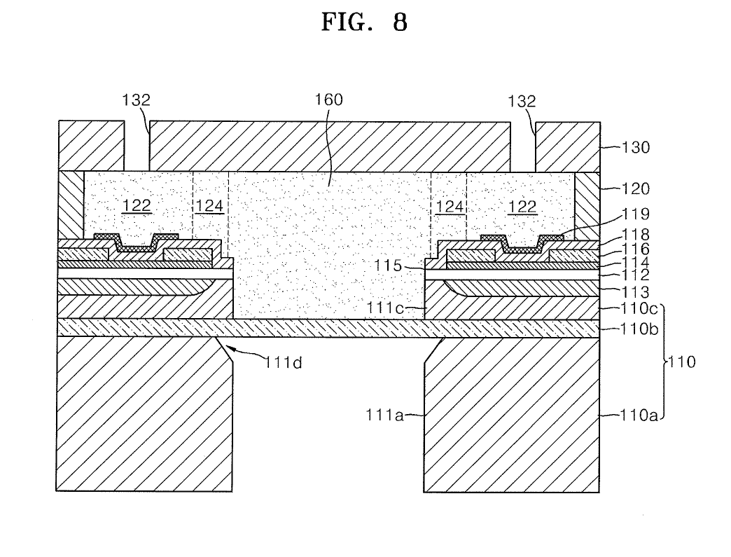

In FIG. 8, the lower feed hole 111a is formed in the lower silicon substrate 110a of the SOI substrate 110. More specifically, an etching mask (not illustrated) in which a penetrating hole to expose a region where the lower feed hole 111a is formed is formed on the lower surface of the SOI substrate 110. Here, the etching mask may be arranged for the penetrating hole to be matched with the upper feed hole 111c, however, misalignment may be generated. Then, after the etching mask is formed, the lower feed hole 111a is formed by wet etching or dry etching. During a general etching, an etching speed may vary in each different parts of the substrate. Accordingly, in order to complete forming the lower feed hole 111a in the lower silicon substrate 110a of the SOI substrate 110, a portion of the lower silicon substrate 110a may be over-etched. In this case, an under-cut region 111d may be formed in the lower silicon substrate 110a as illustrated in FIG. 8.

In FIG. 9, the middle feed hole 111b is formed after the lower feed hole 111a is formed and then the sacrificial layer 160 is removed. The middle feed hole 111b is formed by etching the middle insulating layer 110b exposed through the lower feed hole 111a. The sacrificial layer 160 can be removed by inserting a predetermined etchant through the nozzles 132 and lower and middle feed holes 111a and 111b. As such, when the sacrificial layer 160 is removed, the ink chambers 122 and the restrictors 124 are formed in the chamber layer 120. In addition, the trench 115 penetrates the passivation layer 118 and the insulating layer 112, and the upper feed hole 111c connecting the trench 115 to the middle feed hole 111b is formed on the upper silicon substrate 110c.

As described above, in the method of manufacturing the inkjet printhead according to an embodiment of the present general inventive concept, the driving circuit region 113 is formed in the upper silicon substrate of the SOI substrate so that the driving circuit region 113 is safely protected from forming the lower feed hole 111a by the middle insulating layer 110b. Accordingly, the driving circuit region can be protected from the under-cut region accompanied during forming of the lower feed hole 111a by excessive etching process. Also, although misalignment of the lower feed hole 111a may be generated while forming the lower feed hole 111a, the driving circuit region can be prevented from being damaged by the lower feed hole 111a.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An inkjet printhead comprising:
a silicon on insulator (SOI) substrate comprising a lower silicon substrate, a middle insulating layer, an upper silicon substrate, and an ink feed hole, the ink feed hole to penetrate the SOI substrate to supply ink;
an insulating layer stacked on the upper silicon substrate of the SOI substrate;
a chamber layer stacked on the insulating layer in which a plurality of ink chambers filled with ink supplied from the ink feed hole is formed;
a nozzle layer stacked on the chamber layer in which a plurality of nozzles is formed to correspond to the ink chambers;
a plurality of heaters formed on the insulating layer which heats ink in the ink chambers to generate bubbles and eject ink through the nozzles; and
a driving circuit region on which a driving circuit is formed to drive the heaters.

2. The inkjet printhead of claim 1, wherein the driving circuit region is formed in the upper silicon substrate of the SOI substrate.

3. The inkjet printhead of claim 2, wherein a Complementary Metal-Oxide-Semiconductor (CMOS) circuit is formed in the driving circuit region.

4. The inkjet printhead of claim 3, wherein the middle insulating layer is formed of a silicon oxide.

5. The inkjet printhead of claim 1, wherein the middle insulating layer have a thickness of 0.1-0.5 μm.

6. The inkjet printhead of claim 1, wherein the upper silicon substrate have a thickness of 1-5 μm.

7. The inkjet printhead of claim 1, wherein the ink feed hole comprises a lower feed hole formed in the lower silicon substrate, a middle feed hole formed in the middle insulating layer, and an upper feed hole formed in the upper silicon substrate.

8. A method of manufacturing an inkjet printhead, the method comprising:
preparing a silicon on insulator (SOI) substrate in which a lower silicon substrate, a middle insulating layer, and an upper silicon substrate are sequentially stacked;
forming a driving circuit region in the upper silicon substrate of the SOI substrate and then forming an insulating layer on the upper silicon substrate;
forming heaters and electrodes on the insulating layer;
forming a trench in the insulating layer to expose the upper silicon substrate and then forming an upper feed hole to connect to the trench in the upper silicon substrate;
stacking a chamber layer, in which a plurality of ink chambers is formed, on the insulating layer;
stacking a nozzle layer, in which a plurality of nozzles is formed, on the chamber layer; and
forming a lower feed hole on the lower silicon substrate of the SOI substrate and forming a middle feed hole to connect the lower feed hole and the upper feed hole in the middle insulating layer.

9. The method of claim 8, further comprising:
forming a passivation layer on the insulating layer to cover the heaters and the electrodes, after forming the heaters and the electrodes.

10. The method of claim 9, wherein the trench is formed by sequentially etching the passivation layer and the insulating layer.

11. The method of claim 8, wherein the upper feed hole is formed by etching the upper silicon substrate exposed through the trench.

12. The method of claim 8, further comprising:
forming a sacrificial layer to fill the upper feed hole, the trench, and the ink chambers, after stacking the chamber layer.

13. The method of claim 12, wherein the lower feed hole is formed by etching the lower silicon substrate disposed at the lower part of the upper feed hole for the middle insulating layer to be exposed.

14. The method of claim 13, wherein the middle feed hole is formed by etching the middle insulating layer exposed through the lower feed hole for the sacrificial layer to be exposed.

15. The method of claim 13, further comprising:
removing the sacrificial layer after forming the middle feed hole.
